(19) United States
(12) Patent Application Publication
(10) Pub. No.: US 2024/0063059 A1
(43) Pub. Date: Feb. 22, 2024

(54) METHOD OF MANUFACTURING SEMICONDUCTOR DEVICE

(71) Applicant: RENESAS ELECTRONICS CORPORATION, Tokyo (JP)

(72) Inventors: Koichi ANDO, Tokyo (JP); Toshiyuki HATA, Tokyo (JP); Kosuke KITAICHI, Tokyo (JP); Hiroi OKA, Tokyo (JP)

(21) Appl. No.: 18/142,825

(22) Filed: May 3, 2023

(30) Foreign Application Priority Data
Aug. 16, 2022 (JP) 2022-129627

(51) Int. Cl. H01L 21/784; H01L 29/06; H01L 29/66; H01L 21/66

(52) U.S. Cl. CPC H01L 21/784; H01L 29/0649; H01L 29/66712; H01L 22/30; H01L 22/12

(57) ABSTRACT

In a case where a crack occurs in a dicing step, the crack can be suppressed from proceeding toward an element region. A first scribe region and a second scribe region that both define an element region are formed in a main surface of a semiconductor wafer. In the first scribe region, an evaluation-deep-trench group including an evaluation-deep-trench-first portion and an evaluation-deep-trench-second portion is formed. The evaluation-deep-trench-first portion is formed in a first region. The evaluation-deep-trench-second portion has a width in an X-axis direction, and is formed in a bar shape extending in a Y-axis direction, in a second region located between the first region and the element region.

### CROSS-REFERENCE TO RELATED APPLICATION

The disclosure of Japanese Patent Application No. 2022-129627 filed on Aug. 16, 2022, including the specification, drawings and abstract is incorporated herein by reference in its entirety.

### BACKGROUND

The present invention relates to a method of manufacturing a semiconductor device, and is also preferably applicable to, for example, a semiconductor device in which a relatively deep groove is formed.

There are disclosed techniques listed below.
[Patent Document 1] Japanese Unexamined Patent Application Publication No. 2019-33148
[Patent Document 2] Japanese Unexamined Patent Application Publication No. 2019-114643
[Patent Document 3] Japanese Unexamined Patent Application Publication No. 2015-37099

As a semiconductor device, there is a semiconductor device in which a relatively deep groove of, for example, 1 μm or more is formed on a semiconductor substrate. Here, this relatively deep groove is referred to as a deep trench. For example, the Patent Document 1 proposes a method of forming a super junction structure in which p-n junctions are periodically arranged by implanting n-type impurities and p-type impurities via the deep trench into an element region where a semiconductor element is formed.

The Patent Document 2 proposes a method of forming a field plate type field effect transistor in which a field plate electrode and a gate electrode are disposed in the deep trench in an element region. The Patent Document 3 proposes a method of forming a substrate contact in one deep trench in an element region and forming an element separator in another deep trench.

### SUMMARY

As described above, in the Patent Document 1, the deep trench is formed in order to form the super junction structure in the element region. In the Patent Document 2, the deep trench is formed in order to form the field plate type field effect transistor in the element region. In the Patent Document 3, the deep trench is formed in order to form the substrate contact and the element isolation region in the element region.

On the other hand, the present inventors have studied forming an evaluation deep trench in a scribe region in order to check whether or not the deep trench formed in the element region has a desired shape.

Specifically, the shape including a depth, a dimension, and an angle, etc., of the evaluation deep trench formed in the scribe region is evaluated by using, for example, an optical critical dimension (OCD). The present inventors have studied forming a line-and-space pattern as the evaluation deep trench formed in the scribe region in order to improve accuracy in the optical evaluation. The “line-and-space pattern” referred to herein is a pattern in which a plurality of deep trenches (that is, a linear pattern) extending in one direction are arranged to be spaced apart from each other in another direction intersecting the one direction.

A semiconductor wafer on which a wafer process has been completed is divided into individual semiconductor chips by cutting the scribe regions with a dicing blade.

Here, in recent years, for example, in order to reduce the semiconductor device manufacturing cost, the number of semiconductor chips acquired from one semiconductor wafer tends to be increased by narrowing (thinning) a width of the scribe region of the semiconductor wafer. Accordingly, a width (thickness) of a dicing blade used in a dicing step also tends to be reduced (small). On the other hand, in order to improve the accuracy in the checking of whether the deep trench formed in the element region has a desired shape, a size of the line-and-space pattern (that is, the evaluation deep trench) formed in the scribe region is preferably large.

As a result, in the line-and-space pattern formed in the scribe region, a portion located in a kerf region through which the dicing blade passes is removed, while a portion located between the kerf region and the element region remains.

From the studies made by the present inventors, it has been found out that, depending on how to dispose the line-and-space pattern, a crack starting from an end of the line-and-space pattern remaining between the kerf region and the element region occurs in the semiconductor substrate when the line-and-space pattern located in the kerf region is removed. If the crack progresses to the element region, it is assumed that the semiconductor device (semiconductor chip) may become defective.

Other objects and novel characteristics will be apparent from the description herein and the accompanying drawings.

A method of manufacturing a semiconductor device according to an embodiment is a method of manufacturing a semiconductor device including a semiconductor element formed in each of a plurality of element regions defined in a semiconductor substrate, and includes the following four steps. A semiconductor substrate having a main surface is prepared. A plurality of scribe regions including a plurality of first scribe regions each extending in a first direction and arranged to be spaced apart from each other in a second direction intersecting the first direction are defined in the main surface of the semiconductor substrate. The semiconductor element is formed in each of the plurality of element regions defined in a matrix form by the plurality of scribe regions. By cutting each of the plurality of scribe regions with the dicing blade, the element region in which the semiconductor element is formed is obtained as a semiconductor chip. The step of forming the semiconductor element includes the following two steps. A first trench is formed in each of the plurality of element regions, and a trench group comprised of a plurality of second trenches is formed in each of the plurality of first scribe regions. The trench group is evaluated. The step of forming the trench group comprised of the plurality of second trenches includes a step of forming a second-trench-first portion in a first region of one of the plurality of first scribe regions to be removed by the dicing blade, and forming a second-trench-second portion in a second region of the one of the plurality of first scribe regions, the second region being located between the first region of the one of the plurality of first scribe regions and one of the plurality of element regions, the one of the plurality of element regions being adjacent to the one of the plurality of first scribe regions including the first region. In plan view, the second-trench-second portion is formed in a bar shape extending in a first direction in which each of the plurality of first scribe regions extends.

A method of manufacturing a semiconductor device according to another embodiment is a method of manufacturing a semiconductor device including a semiconductor element formed in each of a plurality of element regions defined in a semiconductor substrate, and includes the following four steps. A semiconductor substrate having a main surface is prepared. A plurality of first scribe regions each extending in a first direction and arranged to be spaced apart from each other in a second direction intersecting the first direction and a plurality of second scribe regions each extending in the second direction and arranged to be spaced apart from each other in the first direction are defined in the main surface of the semiconductor substrate. The semiconductor element is formed in each of the plurality of element regions defined in a matrix form by the plurality of first scribe regions and the plurality of second scribe regions. By cutting the first scribe region and the second scribe region with a dicing blade, the element region in which the semiconductor element is formed is obtained as a semiconductor chip. The step of forming the semiconductor elements includes the following two steps. A first trench is formed in each of the plurality of element regions, and a trench group comprised of a plurality of second trenches is formed in an intersection region where the first scribe region and the second scribe region intersect each other. The trench group is evaluated. In the step of forming the trench group, all of the plurality of second trenches are formed to be located in a portion of the intersection region, the portion being removed by the dicing blade.

A method of manufacturing a semiconductor device according to still another embodiment is a method of manufacturing a semiconductor device including a semiconductor element formed in each of a plurality of element regions defined in a semiconductor substrate, and includes the following four steps. A semiconductor substrate having a main surface is prepared. A plurality of first scribe regions each extending in a first direction and arranged to be spaced apart from each other in a second direction intersecting the first direction and a plurality of second scribe regions each extending in the second direction and arranged to be spaced apart from each other in the first direction are defined in the main surface of a semiconductor substrate. The semiconductor element is formed in each of the plurality of element regions defined in a matrix form by the plurality of first scribe regions and the plurality of second scribe regions. By cutting the first scribe region and the second scribe region with a dicing blade, the element region in which the semiconductor element is formed is obtained as a semiconductor chip. The step of forming the semiconductor element includes the following two steps. A first trench is formed in each of the plurality of element regions, and a trench group comprised of a plurality of second trenches is formed in an intersection region where the first scribe region and the second scribe region intersect each other. The trench group is evaluated. In the step of forming the trench group comprised of the plurality of second trenches, each of the plurality of second trenches is annularly formed to extend along a cleavage plane of the semiconductor substrate.

According to the method of manufacturing the semiconductor device according to an embodiment, the semiconductor device can be suppressed from becoming a defective product.

According to the method of manufacturing the semiconductor device according to another embodiment, the semiconductor device can be suppressed from becoming a defective product.

According to a method of manufacturing the semiconductor device according to still another embodiment, the semiconductor device can be suppressed from becoming a defective product.

### BRIEF DESCRIPTIONS OF THE DRAWINGS

FIG. 1 is a plan view illustrating a semiconductor wafer according to each embodiment.

FIG. 2 is a partial plan view illustrating a scribe region and an element region in the semiconductor wafer according to a first embodiment.

FIG. 3 is a view illustrating a cross-sectional structure along a cross-sectional line in FIG. 2 and a planar structure shown in a dotted frame illustrated in FIG. 2 in the same embodiment.

FIG. 4 is a cross-sectional view illustrating one step in a method of manufacturing the semiconductor device in the same embodiment.

FIG. 5 is a cross-sectional view illustrating a step performed after the step illustrated in FIG. 4 in the same embodiment.

FIG. 6 is a partial cross-sectional view illustrating a step performed after the step illustrated in FIG. 5 in the same embodiment.

FIG. 7 is a cross-sectional view illustrating a step performed after the step illustrated in FIG. 6 in the same embodiment.

FIG. 8 is a cross-sectional view illustrating a step performed after the step illustrated in FIG. 7 in the same embodiment.

FIG. 9 is a cross-sectional view illustrating a step performed after the step in FIG. 8 in the first embodiment.

FIG. 10 is a cross-sectional view illustrating a step performed after the step in FIG. 9 in the same embodiment.

FIG. 11 is a cross-sectional view illustrating a step performed after the step in FIG. 10 in the same embodiment.

FIG. 12 is a cross-sectional view illustrating a step performed after the step in FIG. 11 in the same embodiment.

FIG. 13 is a cross-sectional view illustrating a step performed after the step in FIG. 12 in the same embodiment.

FIG. 14 is a partially enlarged plan view illustrating a step performed after the step in FIG. 13 in the same embodiment.

FIG. 15 is a partially enlarged plan view illustrating a step performed after the step in FIG. 14 in the same embodiment.

FIG. 16 is a plan view illustrating a step performed after the step in FIG. 15 in the same embodiment.

FIG. 17 is a partially enlarged plan view illustrating one step in a method of manufacturing a semiconductor device according to a comparative example.

FIG. 18 is a partially enlarged plan view illustrating a step performed after the step in FIG. 17.

FIG. 19 is a partially enlarged plan view illustrating a scribe region and a surrounding region of the scribe region in a semiconductor wafer according to a second embodiment.

FIG. 20 is a partially enlarged plan view illustrating one step in a method of manufacturing a semiconductor device in the same embodiment.

FIG. 21 is a partially enlarged plan view illustrating a scribe region and a surrounding region of the scribe region in a semiconductor wafer according to a third embodiment.

FIG. 22 is a partially enlarged plan view illustrating one step in a method of manufacturing a semiconductor device in the same embodiment.

FIG. 23 is a partially enlarged plan view illustrating a step performed after the step in FIG. 22 in the same embodiment.

FIG. 24 is a partially enlarged plan view illustrating a scribe region and a surrounding region of the scribe region in a semiconductor wafer according to a fourth embodiment.

FIG. 25 is a partially enlarged plan view illustrating one step in a method of manufacturing a semiconductor device in the same embodiment.

FIG. 26 is a partially enlarged plan view illustrating a step performed after the step in FIG. 25 in the same embodiment.

FIG. 27 is a plan view illustrating a semiconductor wafer according to a first example of a fifth embodiment.

FIG. 28 is a partially enlarged plan view illustrating a scribe region and a surrounding region of the scribe region in the semiconductor wafer according to the first example of the same embodiment.

FIG. 29 is a partially enlarged plan view illustrating one step in a method of manufacturing a semiconductor device to which the semiconductor wafer according to the first example is applied in the same embodiment.

FIG. 30 is a partially enlarged plan view illustrating a step performed after the step in FIG. 29 in the same embodiment.

FIG. 31 is a plan view illustrating a semiconductor wafer according to a second example of the fifth embodiment.

FIG. 32 is a partially enlarged plan view illustrating a scribe region and a surrounding region of the scribe region in a semiconductor wafer according to the second example of the same embodiment.

FIG. 33 is a partially enlarged plan view illustrating one step in a method of manufacturing a semiconductor device to which the semiconductor wafer according to the second example is applied in the same embodiment.

FIG. 34 is a partially enlarged plan view illustrating a step performed after the step in FIG. 33 in the same embodiment.

FIG. 35 is a partial plan view illustrating a scribe region and an element region in a semiconductor wafer according to a sixth embodiment.

FIG. 36 is a partially enlarged plan view illustrating the scribe region and the surrounding region of the scribe region in the semiconductor wafer in the same embodiment.

FIG. 37 is a partially enlarged plan view illustrating one step in a method of manufacturing a semiconductor device in the same embodiment.

FIG. 38 is a plan view illustrating a step performed after the step in FIG. 37 in the same embodiment.

FIG. 39 is a partially enlarged cross-sectional view illustrating a structure in a deep trench in a semiconductor wafer according to a first modification example in each embodiment.

FIG. 40 is a partially enlarged cross-sectional view illustrating a structure in a deep trench in a semiconductor wafer according to a second modification example in each embodiment.

### DETAILED DESCRIPTION

### First Embodiment

An example of a semiconductor wafer on which a semiconductor device is formed and an example of a method of manufacturing the semiconductor device according to a first embodiment will be described. For convenience of description, the description will be made by using X-Y orthogonal coordinates as necessary.

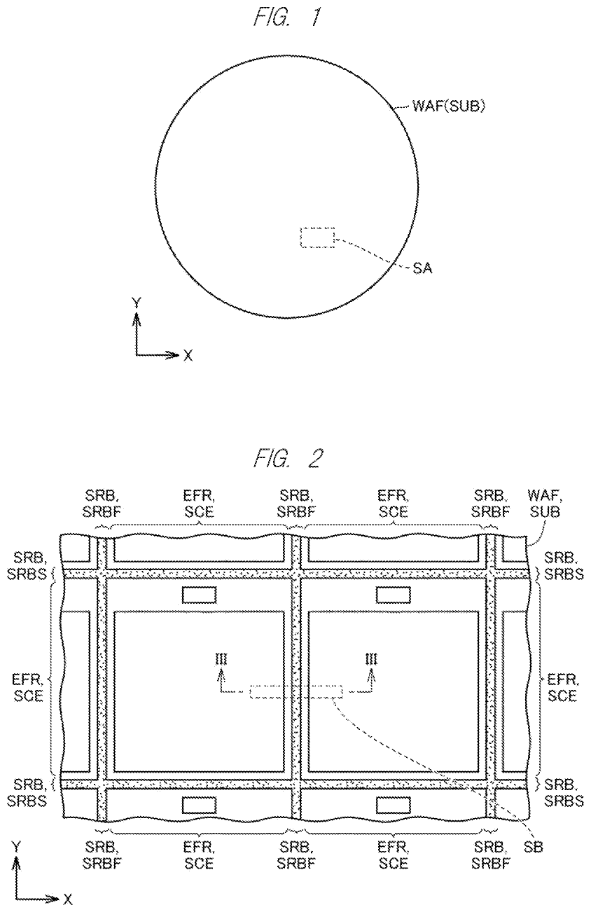

As illustrated in FIGS. 1 and 2, a plurality of scribe regions SRB are defined in a main surface of a semiconductor wafer WAF (semiconductor substrate SUB). Note that FIG. 2 illustrates a planar structure in a dotted frame SA illustrated in FIG. 1. The plurality of scribe regions SRB each include a first scribe region SRBF and a second scribe region SRBS. The first scribe regions SRBF each extend in a Y-axis direction (first direction), and are defined to be spaced apart from each other in an X-axis direction (second direction). The second scribe regions SRBS each extend in the X-axis direction and are defined to be spaced apart from each other in the Y-axis direction. A plurality of element regions EFR are defined in a matrix form by the first scribe regions SRBF and the second scribe regions SRBS.

Next, a structure in a dotted frame SB illustrated in FIG. 2 will be described. First, the element region EFR will be described. A semiconductor element SCE is formed in each element region EFR. Here, as an example of the semiconductor element SCE, a metal oxide semiconductor field effective transistor (MOSFET) having a super junction structure is exemplified. As illustrated in FIG. 3, the semiconductor substrate SUB includes an n⁺⁺-type substrate NPSB, an n-type epitaxial layer NEL, and a p-type epitaxial layer PEL. A p-type base diffusion layer BDL is formed to have a predetermined depth from the main surface of the semiconductor substrate SUB. An n-type column layer NCL reaching the n-type epitaxial layer NEL from the bottom of the base diffusion layer BDL is formed.

A gate trench TRC that penetrates through the base diffusion layer BDL from the main surface of the semiconductor substrate SUB and reaches the n-type column layer NCL is formed. A gate electrode TGEL is formed in the gate trench TRC via a gate insulating film GIF. In the base diffusion layer BDL, an n-type source diffusion layer SDL is formed from the main surface of the semiconductor substrate SUB to a region shallower than the bottom of the base diffusion layer BDL.

An insulator (insulating member) ZOF that penetrates the base diffusion layer BDL and the n-type column layer NCL from the main surface of the semiconductor substrate SUB and reaches the n-type epitaxial layer NEL is formed. The insulator ZOF is formed in the deep trench DTC (first trench). A depth DDT of the deep trench DTC is, for example, about several μm. In the present specification, a groove having a depth of about 1.0μ or more is referred to as a deep trench.

A cavity AG is formed in the insulator ZOF. A p-type column layer PCL is formed to be in contact with the insulator ZOF. The p-type column layer PCL is also in contact with the n-type column layer NCL. The p-type column layer PCL and the n-type column layer NCL are alternately disposed as a super junction structure.

A protective insulating film TPF and an interlayer insulating film ILF are formed to cover the element region EFR. A source electrode SED is formed to cover the interlayer insulating film ILF. A passivation film PVF is formed to cover the source electrode SED. The source electrode SED is electrically connected to the source diffusion layer SDL. The source electrode SED is electrically connected to the base diffusion layer BDL.

Next, the scribe region SRB will be described. An evaluation-deep-trench group EDTG (trench group) for optically evaluating the deep trench DTC formed in the element region EFR is formed in the scribe region SRB. The evaluation-deep-trench group EDTG is made of a plurality of evaluation deep trenches EDC (second trenches).

The evaluation-deep-trench group EDTG (trench group) made of the plurality of evaluation deep trenches EDC is formed as, for example, a line-and-space pattern in order to improve accuracy in the optical evaluation. Specifically, one evaluation deep trench EDC has, for example, a linear shape extending along the Y-axis direction, and a plurality of the linear evaluation deep trenches EDC are patterned in a stripe form while being spaced apart from each other in the X-axis direction.

The plurality of evaluation deep trenches EDC include an evaluation-deep-trench-first portion EDCF (second-trench-first portion) and an evaluation-deep-trench-second portion EDCS (second-trench-second portion). The evaluation-deep-trench-first portion EDCF is formed in a kerf region KF (first region) to be removed by the dicing blade in the scribe region SRB.

The evaluation-deep-trench-second portion EDCS is formed in a portion of the scribe region SRB located between the kerf region KF and the element region EFR adjacent to the scribe region SRB including the kerf region KF in which the evaluation-deep-trench-first portion EDCF is formed. That is, the evaluation-deep-trench-second portion EDCS is formed in a region NK (second region) of the scribe region SRB remaining after the scribe region SRB is cut by the dicing blade. In plan view, the evaluation-deep-trench-second portion EDCS has a width in the X-axis direction and is formed in a bar shape extending along the Y-axis direction. The evaluation-deep-trench-second portion EDCS is formed to extend along one side of the element region EFR.

The insulator ZOF is embedded in each of the evaluation-deep-trench groups EDTG. A cavity AG is formed in the insulator ZOF. In the scribe region SRB, a p-type impurity region corresponding to the p-type column layer PCL formed in the element region EFR is formed to be in contact with the insulator ZOF. In the scribe region SRB, an n-type impurity region corresponding to the n-type column layer NCL formed in the element region EFR is formed to be in contact with the p-type impurity region.

The semiconductor wafer WAF including the semiconductor element SCE formed in the element region EFR according to the first embodiment is configured as described above.

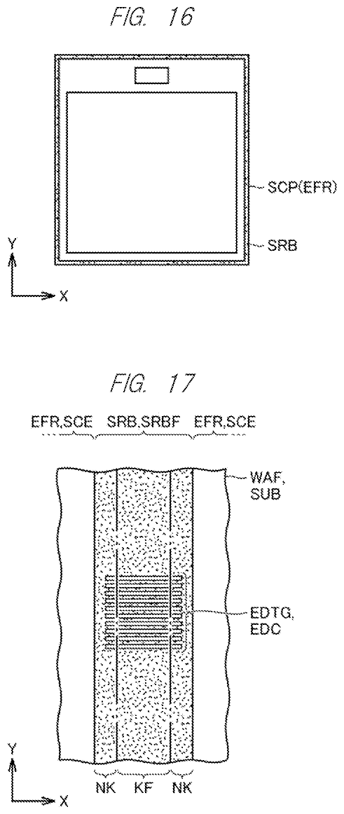

Next, an example of a method of sequentially manufacturing the semiconductor device including the above-described method of manufacturing the semiconductor wafer WAF and the manufacturing method of obtaining the semiconductor chip SCP (see FIG. 16) serving as the semiconductor device from the semiconductor wafer WAF will be described.

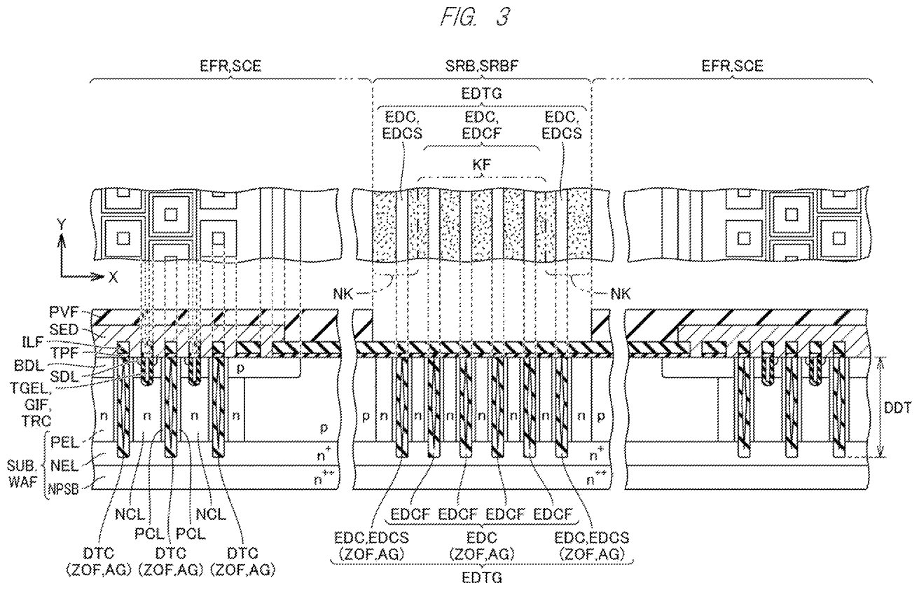

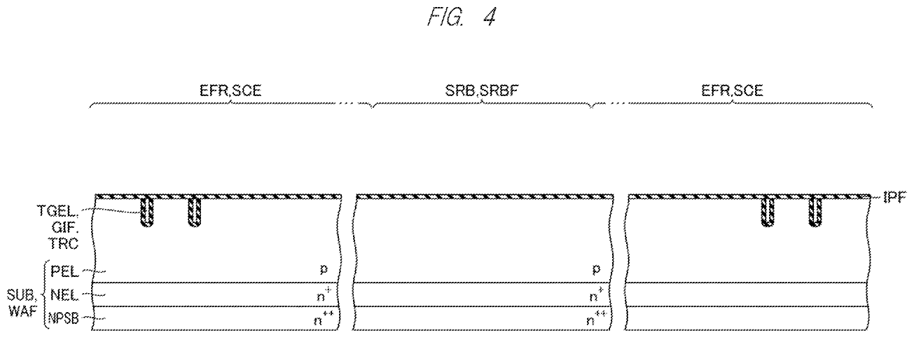

First, the semiconductor substrate SUB (semiconductor wafer WAF) (see FIG. 4) including the n⁺⁺-type substrate NPSB, the n-type epitaxial layer NEL, and the p-type epitaxial layer PEL is prepared. Next, the first scribe region SRBF and the second scribe region SRBS orthogonal to each other are defined in the main surface of the semiconductor substrate SUB. In the main surface of the semiconductor substrate SUB, a plurality of element regions EFR are defined in a matrix form by the first scribe regions SRBF and the second scribe regions SRBS (see FIG. 2).

Next, in the element region EFR, the gate trench TRC (see FIG. 4) having a predetermined depth from the surface of the semiconductor substrate SUB (p-type epitaxial layer PEL) is formed. Next, thermal oxidation treatment is performed to form a silicon oxide film (not illustrated) on the surface of the p-type epitaxial layer PEL including a portion of the p-type epitaxial layer PEL exposed in the gate trench TRC. Next, a polysilicon film (not illustrated) is formed to fill the gate trench TRC.

Next, a portion of the silicon oxide film and a portion of the polysilicon film located on the upper surface of the p-type epitaxial layer PEL are removed. As a result, as illustrated in FIG. 4, a portion of the silicon oxide film remaining in the gate trench TRC is formed as the gate insulating film GIF. A portion of the polysilicon film remaining in the gate trench TRC is formed as the gate electrode TGEL. Next, a thermal oxidation treatment is performed to form the protective insulating film IPF on the surface of the p-type epitaxial layer PEL.

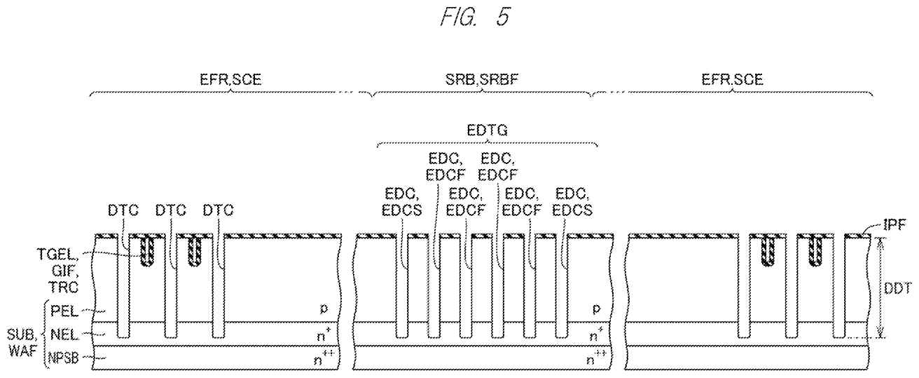

Next, predetermined photoengraving process and etching process are performed. As a result, as illustrated in FIG. 5, the deep trench DTC having the depth DDT is formed in the element region EFR. In this case, in the scribe region SRB, the evaluation-deep-trench group EDTG for optically evaluating the depth of the deep trench DTC and the like is simultaneously formed. The evaluation-deep-trench group EDTG includes the evaluation-deep-trench-first portion EDCF and the evaluation-deep-trench-second portion EDCS.

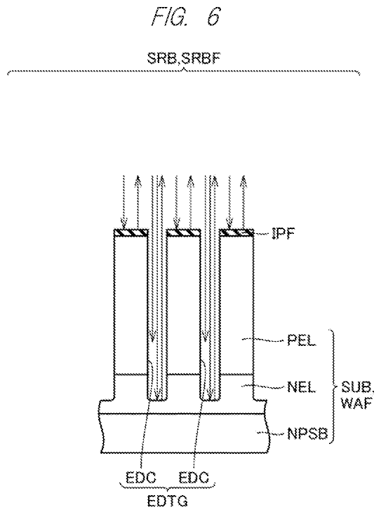

Next, the evaluation-deep-trench group EDTG is evaluated by an optical method (OCD). As illustrated in FIG. 6, the shape such as the depth of the evaluation-deep-trench group EDTG is measured when the scribe region SRB (semiconductor substrate SUB) in which the evaluation-deep-trench group EDTG is formed is irradiated with predetermined light, and then, reflected light is received. Information regarding the measured shape such as depth of the evaluation-deep-trench group EDTG is handled as information corresponding to the shape such as the depth of the deep trench DTC. On the basis of the measurement result, it is determined whether the desired deep trench DTC is formed. Note that an evaluation method based on the evaluation-deep-trench group EDTG is not limited to the optical method if the information corresponding to the shape of the deep trench DTC can be acquired, and other evaluation methods may be employed.

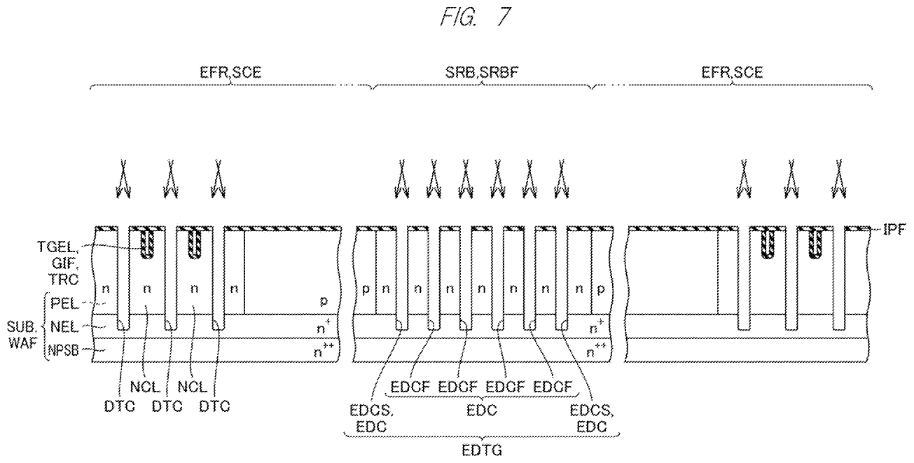

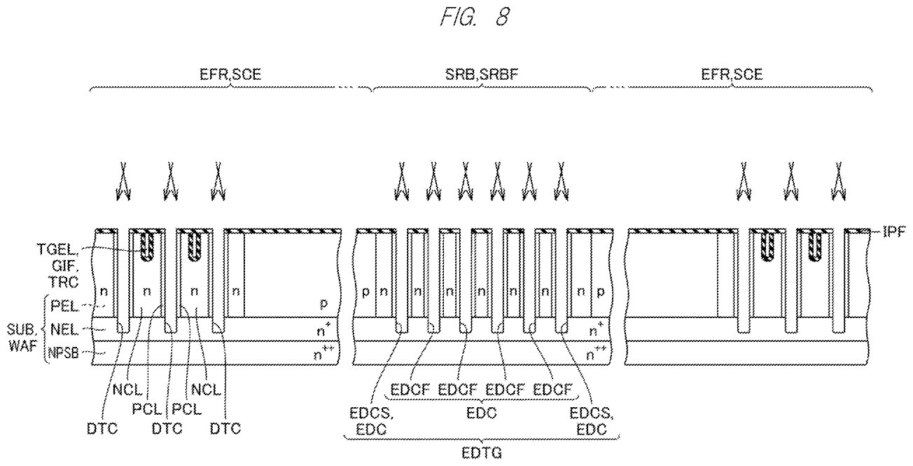

Next, as illustrated in FIG. 7, n-type impurities are obliquely implanted through the protective insulating film IPF, the deep trench DTC, and the like, and heat treatment is performed to form the n-type column layer NCL in the element region EFR. In the scribe region SRB, an n-type impurity region is formed. Next, as illustrated in FIG. 8, p-type impurities are obliquely implanted through the deep trench DTC or the like, and heat treatment is performed to form a p-type column layer PCL in the element region EFR. In the scribe region SRB, a p-type impurity region is formed.

Next, as illustrated in FIG. 9, an insulating film ZOFF such as a silicon oxide film is formed to fill the deep trench DTC and the evaluation deep trench EDC. In this case, the cavity AG is formed in the deep trench DTC and the evaluation deep trench EDC sufficiently deeper than the gate trench TRC.

Next, chemical mechanical polishing (CMP) is performed. Therefore, a portion of the insulating film ZOFF located on the upper surface of the semiconductor substrate SUB is removed while a portion of the insulating film ZOFF located in each of the deep trench DTC and the evaluation deep trench EDC remains. Consequently, as illustrated in FIG. 10, in the element region EFR, the insulator ZOF having the cavity AG is formed in the deep trench DTC. In the scribe region SRB, the insulator ZOF having the cavity AG is formed in the evaluation-deep-trench group EDTG.

Next, by performing thermal oxidation treatment, the surface of the semiconductor substrate SUB is oxidized to form the protective insulating film TPF (see FIG. 11). Next, a predetermined photoresist pattern (not illustrated) for forming the base diffusion layer BDL is formed by performing a photoengraving process. Next, p-type impurities are implanted while the photoresist pattern (not illustrated) is used as an implantation mask. As a result, as illustrated in FIG. 11, the p-type base diffusion layer BDL is formed. The base diffusion layer BDL is formed from the surface of the semiconductor substrate SUB to a position shallower than the bottom of the gate trench TRC. Then, the photoresist pattern is removed.

Next, a predetermined photoresist pattern (not illustrated) for forming the source diffusion layer SDL is formed by performing a photoengraving process. Next, n-type impurities are implanted while the photoresist pattern is used as an implantation mask. Thus, the source diffusion layer SDL is formed in the element region EFR. The source diffusion layer SDL is formed from the surface of the base diffusion layer BDL to a position shallower than the bottom of the base diffusion layer BDL. Then, the photoresist pattern is removed.

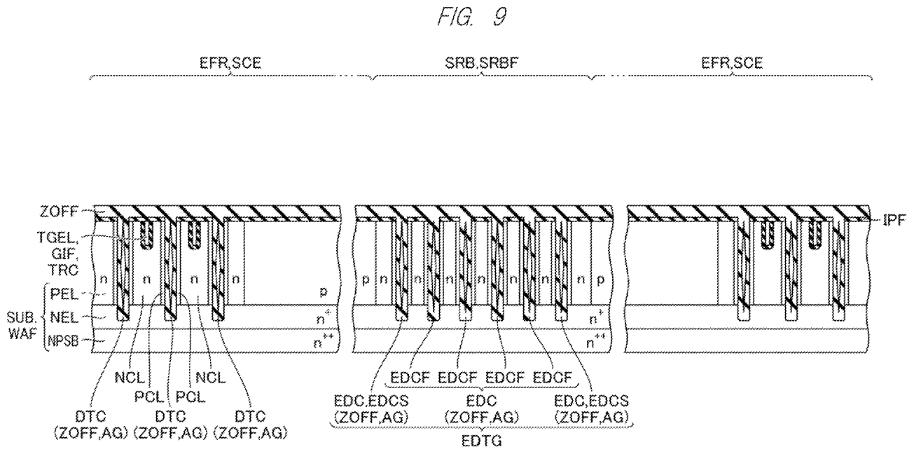

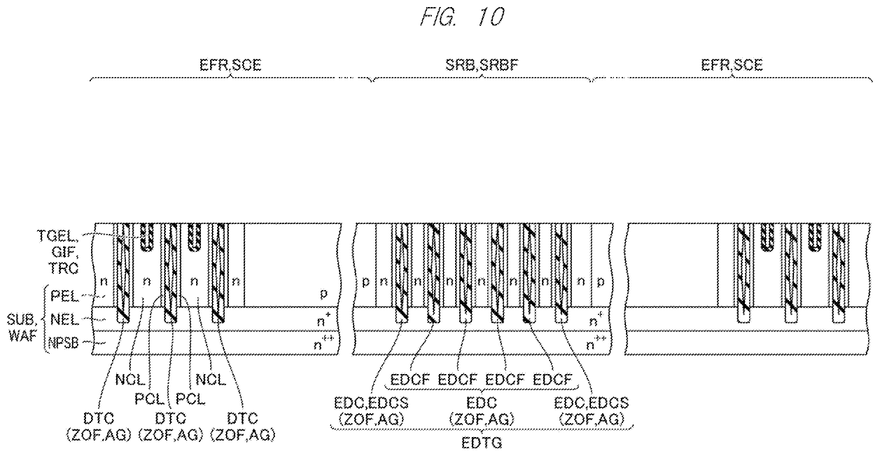

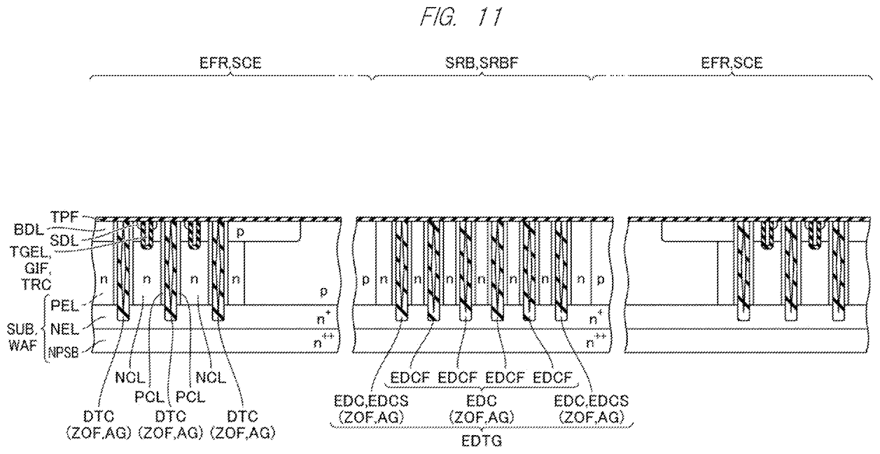

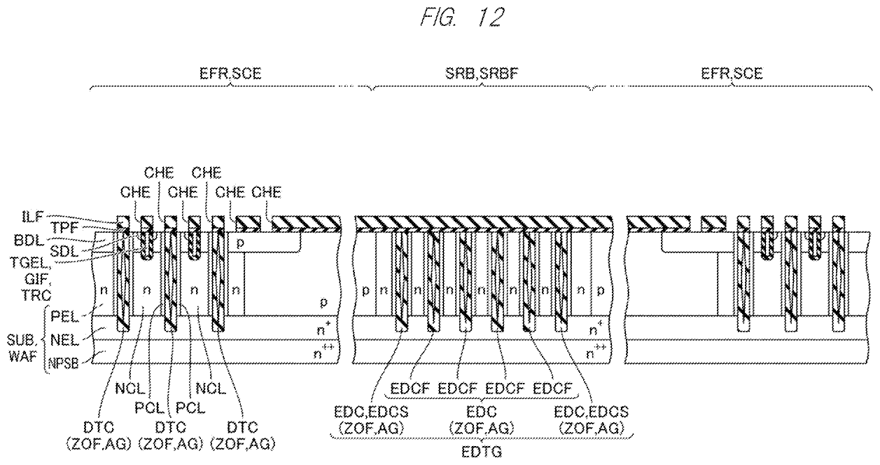

Next, an interlayer insulating film ILF (see FIG. 12) is formed to cover the semiconductor substrate SUB (protective insulating film TPF). Next, predetermined photoengraving process and etching process are performed to the interlayer insulating film ILF. Consequently, as illustrated in FIG. 12, an opening CHE through which the source diffusion layer SDL and the base diffusion layer BDL are exposed is formed.

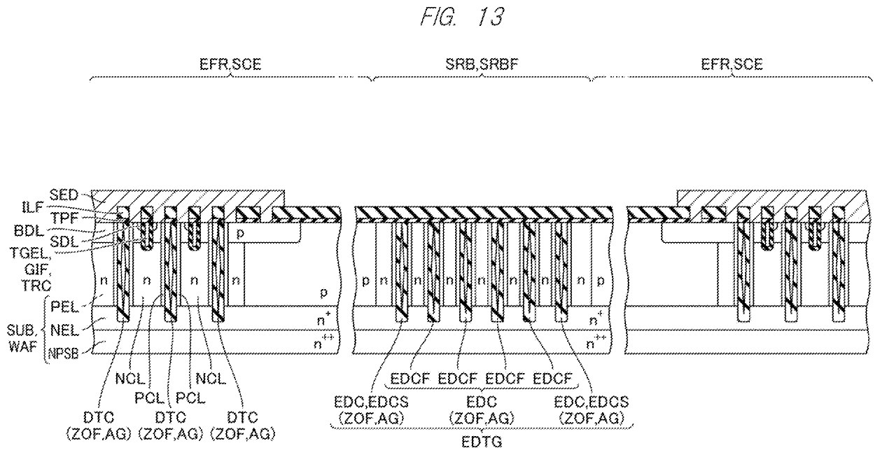

Next, an aluminum film (not illustrated) is formed to cover the interlayer insulating film ILF by, for example, a sputtering method. Next, predetermined photoengraving process and etching process are performed to the aluminum film. As a result, as illustrated in FIG. 13, the source electrode SED is formed. Next, the passivation film PVF (see FIG. 3) is formed to cover the source electrode SED and the like to complete the semiconductor wafer WAF illustrated in FIGS. 1 to 3.

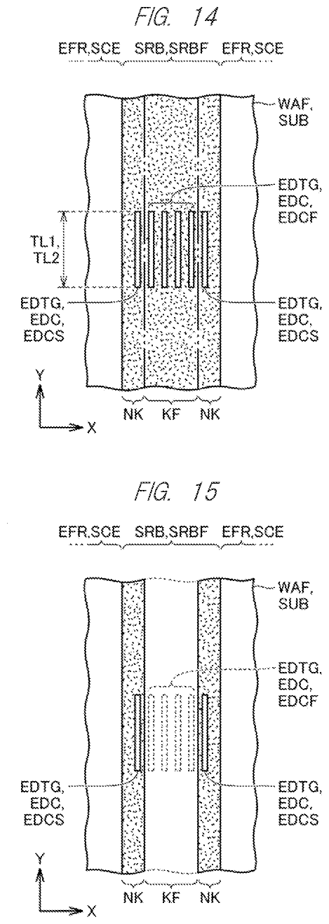

Next, a dicing step of obtaining, as the semiconductor chip SCP (see FIG. 16), the element regions EFR in each of which the semiconductor element SCE is formed from the semiconductor wafer WAF is performed. As illustrated in FIG. 14, in the first scribe region SRBF of the scribe region SRB where dicing is performed, the evaluation-deep-trench group EDTG in which the insulator ZOF (see FIG. 3) is formed is formed.

A plurality of evaluation-deep-trench-first portions EDCF are located in the kerf region KF of the scribe region SRB (first scribe region SRBF), the kerf region being removed by the dicing blade. The evaluation-deep-trench-second portion EDCS is located in a region NK of the scribe region SRB (first scribe region SRBF) located between the kerf region KF and the element region EFR adjacent to the scribe region SRB including the kerf region KF in which the evaluation-deep-trench-first portion EDCF is formed. A length TL2 of the evaluation-deep-trench-second portion EDCS in the Y-axis direction is substantially the same as a length TL1 of the evaluation-deep-trench-first portion EDCF in the Y-axis direction.

First, a plurality of first scribe regions SRBF are sequentially diced (cut) by the dicing blade (not illustrated). As a result, as illustrated in FIG. 15, the evaluation-deep-trench-first portion EDCF located in the kerf region KF is removed. On the other hand, the evaluation-deep-trench-second portion EDCS remains in the region NK of the scribe region SRB (first scribe region SRBF) located between the kerf region KF and the element region EFR and not being removed by the dicing blade.

Next, the plurality of second scribe regions SRBS are sequentially diced (cut) by the dicing blade (not illustrated). Through this dicing step, as illustrated in FIG. 16, the element region EFR in which the semiconductor element is formed in the semiconductor wafer WAF (see FIG. 1) is obtained as the semiconductor chip SCP. As described above, the semiconductor chip SCP serving as the semiconductor device is completed.

In a method of sequentially manufacturing the semiconductor device as described above, the evaluation-deep-trench-second portion EDCS in which the insulator ZOF is formed is formed in the scribe region SRB (first scribe region SRBF). As a result, even if a crack occurs in the dicing step, the crack can be prevented from proceeding to the element region EFR. This will be described in comparison with a method of manufacturing a semiconductor device according to a comparative example.

As illustrated in FIG. 17, in the semiconductor wafer WAF applied to the method of manufacturing the semiconductor device according to the comparative example, an evaluation-deep-trench group EDTG made of a plurality of evaluation deep trenches EDC is formed in a scribe region SRB (first scribe region SRBF). In the evaluation-deep-trench group EDTG, one evaluation deep trench EDC is formed in a linear shape extending along the X-axis direction, and a plurality of the evaluation deep trenches EDC are arranged in a stripe form to be spaced apart from each other in the Y-axis direction.

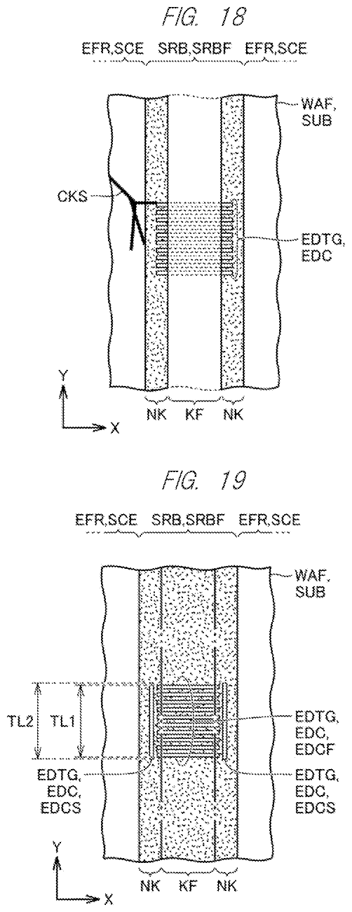

A dicing step is performed to the semiconductor wafer WAF. First, the plurality of first scribe regions SRBF (see FIG. 17) are sequentially diced by the dicing blade. Through this dicing, as illustrated in FIG. 18, in the evaluation-deep-trench group EDTG, a portion of the evaluation deep trench EDC located in the kerf region KF is removed. In the region NK of the scribe region SRB located between the kerf region KF and the element region EFR, a portion including the end of the evaluation deep trench EDC remains.

As illustrated in FIG. 18, at the time of cutting with the dicing blade, a crack CKS may occur at the end of the evaluation deep trench EDC, and the crack CKS may progress toward the element region EFR. As a result, the element region EFR (semiconductor chip) in which the semiconductor element SCE is formed is expected to be a defective product.

In contrast to the method of manufacturing the semiconductor device according to the comparative example, in the method of manufacturing the semiconductor device according to the first embodiment, the evaluation-deep-trench-second portion EDCS in a bar shape extending along the Y-axis direction in which the scribe region SRB (first scribe region SRBF) extends is formed in the region NK of the scribe region SRB (first scribe region SRBF) remaining in the dicing step as illustrated in FIG. 15.

As a result, even if a crack occurs from the evaluation-deep-trench-first portion EDCF located in the kerf region KF during the dicing step, the evaluation-deep-trench-second portion EDCS can prevent the crack from proceeding toward the adjacent element region EFR (semiconductor chip). As a result, the element region EFR (semiconductor chip) in which the semiconductor element SCE is suppressed from becoming a defective product.

Particularly, a case where the insulator ZOF embedded in the evaluation deep trench EDC has the cavity AG is more disadvantageous in terms of strength than that of a structure not having the cavity AG, and is easier to cause the crack. In the above-described method of manufacturing the semiconductor device, even in a situation where the crack is easy to be caused by the dicing step, the crack can be effectively prevented from proceeding toward the element region EFR (semiconductor chip) by the evaluation-deep-trench-second portion EDCS.

### Second Embodiment

In the second embodiment, a first example of a variation of the pattern of the evaluation-deep-trench group EDTG formed in the scribe region SRB will be described.

As illustrated in FIG. 19, in the semiconductor wafer WAF that is a manufacturing target in a method of manufacturing a semiconductor device according to a second embodiment, an evaluation-deep-trench group EDTG made of a plurality of evaluation deep trenches EDC is formed in the scribe region SRB (first scribe region SRBF). The evaluation-deep-trench group EDTG includes an evaluation-deep-trench-first portion EDCF and an evaluation-deep-trench-second portion EDCS. In the evaluation-deep-trench group EDTG, an insulator ZOF having a cavity AG is formed.

The evaluation-deep-trench-first portion EDCF is formed in a linear shape extending along the X-axis direction, and a plurality of the evaluation-deep-trench-first portions EDCF are arranged in a stripe form to be spaced apart from each other in the Y-axis direction. The evaluation-deep-trench-second portion EDCS is formed in a region NK of a scribe region SRB (first scribe region SRBF) located between a kerf region KF and an element region EFR adjacent to the scribe region SRB including the kerf region KF in which the evaluation-deep-trench-first portion EDCF is formed.

The evaluation-deep-trench-second portion EDCS has a width in the X-axis direction, and is formed in a bar shape extending along the Y-axis direction. The evaluation-deep-trench-second portion EDCS has a length TL2 in the Y-axis direction. The evaluation-deep-trench group EDTG has a length TL1 in the Y-axis direction. The length TL2 is desirably larger than the length TL1.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

First, a plurality of first scribe regions SRBF are sequentially diced (cut) by a dicing blade (not illustrated). As a result, as illustrated in FIG. 20, the plurality of evaluation-deep-trench-first portions EDCFs located in the kerf region KF are removed. On the other hand, the evaluation-deep-trench-second portion EDCS remains in the region NK of the scribe region SRB (first scribe region SRBF) that is located between the kerf region KF and the element region EFR and has not been removed. A portion including the end of the evaluation-deep-trench-first portion EDCF remains in the unremoved region NK.

Next, the plurality of second scribe regions SRBS (see FIG. 2) are sequentially diced (cut) by a dicing blade (not illustrated). Through this dicing step, the element region EFR in which the semiconductor element is formed in the semiconductor wafer WAF (see FIG. 1) is obtained as the semiconductor chip SCP (see FIG. 16). As described above, the semiconductor chip SCP serving as the semiconductor device is completed.

In the above-described method of manufacturing the semiconductor device, the insulator ZOF having the cavity AG is formed in the evaluation-deep-trench group EDTG. In the region NK of the scribe region SRB (first scribe region SRBF) remaining in the dicing step, the evaluation-deep-trench-second portion EDCS in a bar shape extending along the Y-axis direction in which the scribe region SRB (first scribe region SRBF) extends is formed. A portion including the end of the evaluation-deep-trench-first portion EDCF also remains in the region NK.

As a result, even if a crack occurs from the end of the evaluation-deep-trench-first portion EDCF or the like during the dicing step, the crack can be effectively prevented from proceeding toward the adjacent element region EFR (semiconductor chip) by the evaluation-deep-trench-second portion EDCS. As a result, the element region EFR (semiconductor chip) in which the semiconductor element SCE is formed can be prevented from becoming a defective product.

### Third Embodiment

In the third embodiment, a second example of a variation of the pattern of the evaluation-deep-trench group EDTG formed in the scribe region SRB will be described.

As illustrated in FIG. 21, in the semiconductor wafer WAF that is a manufacturing target in the method of manufacturing the semiconductor device according to the third embodiment, an evaluation-deep-trench group EDTG made of a plurality of evaluation deep trenches EDC is formed in an intersection region where the first scribe region SRBF and the second scribe region SRBS intersect each other. The evaluation-deep-trench group EDTG includes an evaluation-deep-trench-first portion EDCF (second-trench-first portion) and an evaluation-deep-trench-second portion EDCS (second-trench-second portion). In the evaluation-deep-trench group EDTG, an insulator ZOF (see FIG. 3) having a cavity AG is formed.

The evaluation-deep-trench-first portion EDCF is formed in a linear shape extending along the Y-axis direction, and a plurality of the evaluation-deep-trench-first portions EDCF are arranged in a stripe form to be spaced apart from each other in the X-axis direction. The evaluation-deep-trench-second portion EDCS is formed in the region NK of the scribe region SRB (the first scribe region SRBF and the second scribe region SRBS) located outside the kerf region KF. The evaluation-deep-trench-second portion EDCS has a width in the X-axis direction, and is formed in a bar shape extending along the Y-axis direction. The evaluation-deep-trench-second portion EDCS has a length TL2 in the Y-axis direction. The evaluation-deep-trench-first portion EDCF has a length TL1 in the Y-axis direction. A length TL2 is substantially the same as the length TL1.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

In this dicing step, dicing (cutting) is performed from the first scribe region SRBF in parallel to the direction in which the evaluation-deep-trench-second portion EDCS extends. Next, the second scribe region SRBS is diced (cut).

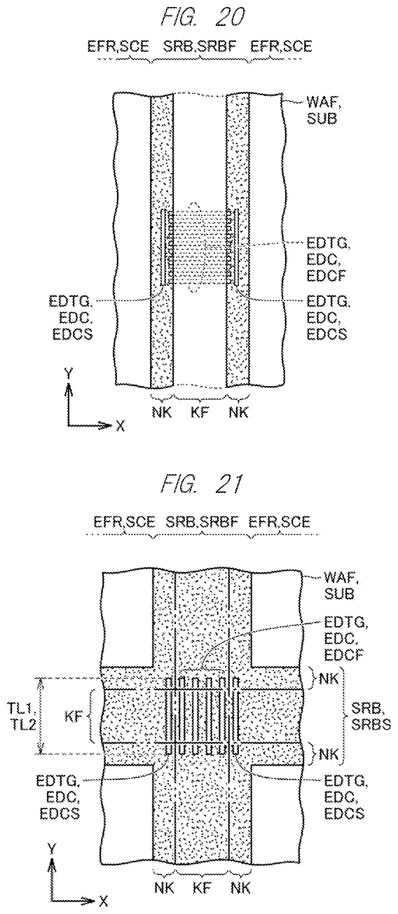

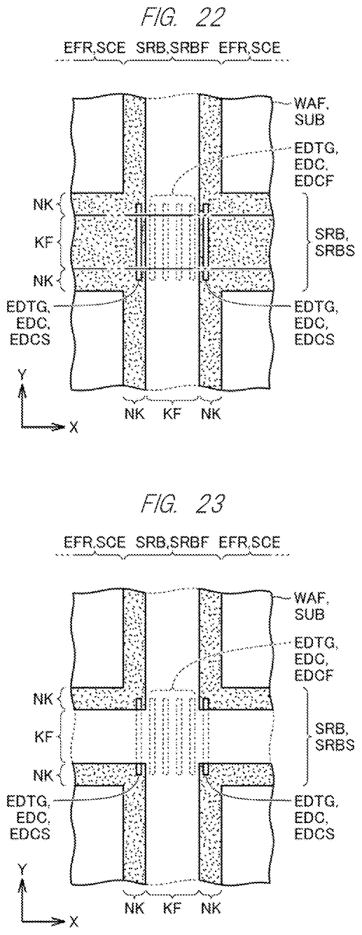

First, a plurality of first scribe regions SRBF are sequentially diced (cut) by a dicing blade (not illustrated). As a result, as illustrated in FIG. 22, the evaluation-deep-trench-first portion EDCF located in the kerf region KF is removed. On the other hand, the evaluation-deep-trench-second portion EDCS remains in the region NK of the scribe region SRB (the first scribe region SRBF and the second scribe region SRBS) that is located outside the kerf region KF and has not been removed.

Next, the plurality of second scribe regions SRBS is sequentially diced (cut) by a dicing blade (not illustrated). As a result, as illustrated in FIG. 23, the element region EFR in which the semiconductor element is formed in the semiconductor wafer WAF is obtained as the semiconductor chip SCP (see FIG. 16). As described above, the semiconductor chip SCP serving as the semiconductor device is completed.

In the above-described method of manufacturing the semiconductor device, the first scribe region SRBF in parallel to the direction in which the evaluation-deep-trench-second portion EDCS extends is diced (cut) first, and then, the second scribe region SRBS is diced (cut).

As a result, even if a crack occurs from the end of the evaluation-deep-trench-first portion EDCF or the like when the first scribe region SRBF is diced (cut), the crack can be effectively prevented from proceeding toward the element region EFR (semiconductor chip) by the evaluation-deep-trench-second portion EDCS.

When the second scribe region SRBS is diced (cut), the portion of the evaluation-deep-trench-second portion EDCS located in the second kerf region KF2 is removed, while a portion including the end of the evaluation-deep-trench-second portion EDCS remains in the region NK of the scribe region SRB that has not been removed.

Here, a case in which the crack occurs from the end of the evaluation-deep-trench-second portion EDCS remaining when the second scribe region SRBS is diced (cut) is assumed. Accordingly, since the evaluation-deep-trench-second portion EDCS is formed in the intersection region where the first scribe region SRBF and the second scribe region SRBS intersect each other, a distance from the end of the evaluation-deep-trench-second portion EDCS to the element region EFR is longer than that in a case in which the evaluation-deep-trench-second portion EDCS is not formed in the intersection region. As a result, the crack caused from the end of the evaluation-deep-trench-second portion EDCS can be suppressed from proceeding toward the element region EFR.

As a result, the element region EFR (semiconductor chip) in which the semiconductor element SCE is formed can be suppressed from becoming a defective product.

### Fourth Embodiment

In a fourth embodiment, a third example of a variation of the pattern of the evaluation-deep-trench group EDTG formed in the scribe region SRB will be described.

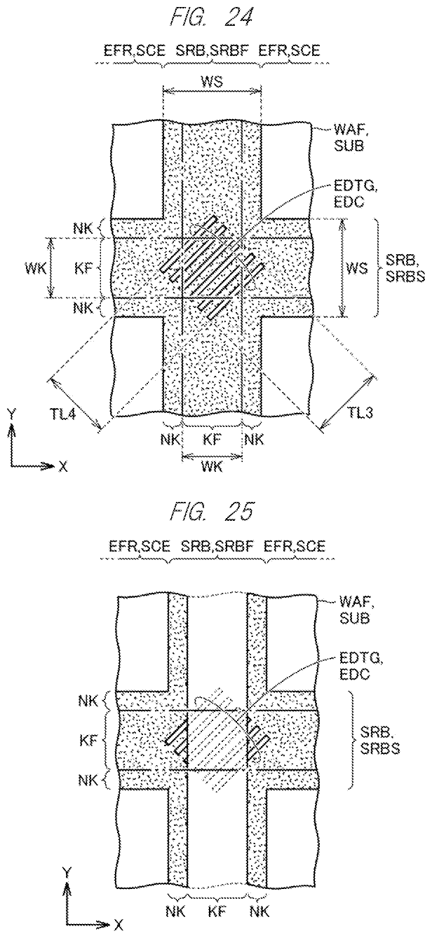

As illustrated in FIG. 24, in the semiconductor wafer WAF that is a manufacturing target in a method of manufacturing a semiconductor device according to the fourth embodiment, an evaluation-deep-trench group EDTG made of a plurality of evaluation deep trenches EDC is formed in an intersection region where the first scribe region SRBF and the second scribe region SRBS intersect each other. In the evaluation-deep-trench group EDTG, an insulator ZOF (see FIG. 3) having a cavity AG is formed.

Each of the plurality of evaluation deep trenches EDC has a width, and is formed in a bar shape extending along a direction intersecting both the X-axis direction and the Y-axis direction. Here, each of the plurality of evaluation deep trenches EDC extends along a direction intersecting at about 45° with both the X-axis direction and the Y-axis direction. The plurality of evaluation deep trenches EDC are formed to be spaced apart from each other in a direction intersecting the extending direction. The plurality of evaluation deep trenches EDC are formed in the kerf region KF to be eventually removed by the dicing blade.

Here, a length in a direction (third direction) in which the evaluation deep trench EDC extends is defined as a length TL3, and a length in a direction (fourth direction) intersecting the direction in which the evaluation deep trench EDC extends is defined as a length TL4. The length TL3 and the length TL4 are larger than a width WK of the kerf region KF. The length TL3 and the length TL4 are smaller than a value (length) of a product of the width WS of the scribe region SRB and a square root (√2) of 2.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

First, a plurality of first scribe regions SRBF are sequentially diced (cut) by a dicing blade (not illustrated). As a result, as illustrated in FIG. 25, the portion of the evaluation deep trench EDC located in the kerf region KF is removed. In this case, a portion including the end of the evaluation deep trench EDC remains in the region NK of the scribe region SRB (the first scribe region SRBF and the second scribe region SRBS) that has not been removed.

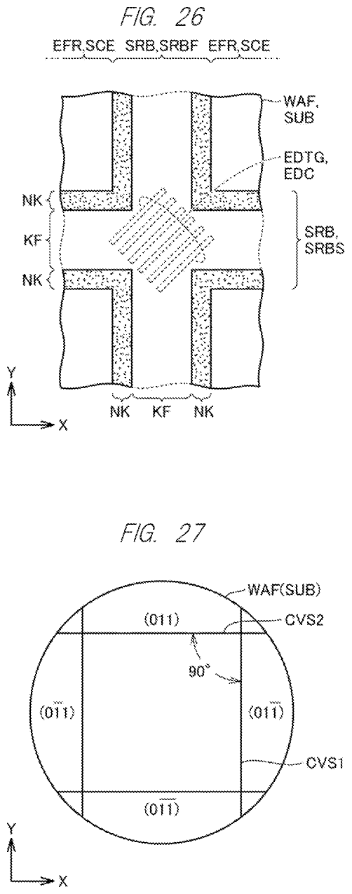

Next, the plurality of second scribe regions SRBS are sequentially diced (cut) by a dicing blade (not illustrated). As a result, as illustrated in FIG. 26, the portion including the end of the remaining evaluation deep trench EDC is removed, and the element region EFR in which the semiconductor element is formed in the semiconductor wafer WAF is obtained as the semiconductor chip SCP (see FIG. 16). As described above, the semiconductor chip SCP serving as the semiconductor device is completed.

In the above-described method of manufacturing the semiconductor device, the evaluation-deep-trench group EDTG is formed in the intersection region where the first scribe region SRBF and the second scribe region SRBS intersect each other. Further, the evaluation-deep-trench group EDTG is formed in the kerf region KF to be eventually removed by the dicing blade. In the evaluation-deep-trench group EDTG, each of the evaluation deep trenches EDC extends along a direction intersecting at about 45° with both the X-axis direction and the Y-axis direction.

As a result, the distance from the end of the evaluation deep trench EDC left by the dicing in the first scribe region SRBF to the element region EFR becomes longer than that in the case where the evaluation deep trench EDC is arranged in parallel to the X-axis direction or the Y-axis direction. Therefore, even if the crack occurs from a portion including an end of the remaining evaluation deep trench EDC when the first scribe region SRBF is diced (cut), the crack can be suppressed from proceeding toward the element region EFR.

A portion including the end of the remaining evaluation deep trench EDC is also eventually removed by the dicing in the second scribe region SRBS. As a result, the element region EFR (semiconductor chip) in which the semiconductor element SCE is formed can be more reliably suppressed from becoming a defective product.

In the evaluation-deep-trench group EDTG, the length TL3 and the length TL4 are larger than the width WK of the kerf region KF. The length TL3 and the length TL4 are smaller than a value (length) of a product of the width WS of the scribe region SRB and a square root (√2) of 2. Consequently, a size of the pattern of the evaluation-deep-trench group EDTG can be made larger than that in a case where the evaluation-deep-trench group EDTG is not inclined with respect to the X-axis direction or the Y-axis direction. As a result, it is possible to improve the accuracy in the optical evaluation of the evaluation-deep-trench group EDTG.

### Fifth Embodiment

In the fifth embodiment, a fourth example of a variation of the pattern of the evaluation deep trench EDC formed in the scribe region SRB will be described. Here, a case where the direction in which the evaluation deep trench extends is parallel to the cleavage plane of the semiconductor wafer WAF will be described separately in two cases.

(Case 1)

In Case 1, a case where an orientation of a notch of the semiconductor wafer WAF is will be described.

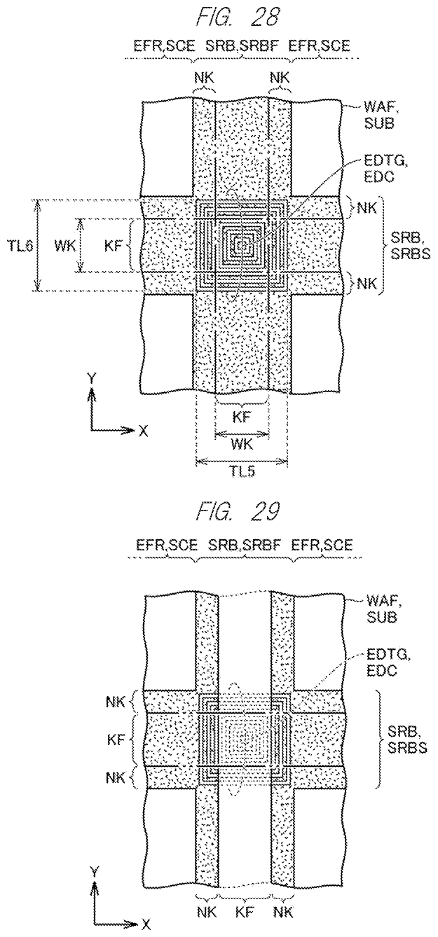

As illustrated in FIGS. 27 and 28, in the semiconductor wafer WAF that is a manufacturing target in the method of manufacturing the semiconductor device, a first cleavage plane CVS1 is in parallel to the Y-axis direction. A second cleavage plane CVS2 is in parallel to the X-axis direction. The first cleavage plane CVS1 and the second cleavage plane CVS2 are orthogonal to each other.

The first scribe region SRBF is in parallel to the first cleavage plane CVS1 (Y-axis direction), and the second scribe region SRBS is in parallel to the second cleavage plane CVS2 (X-axis direction). An evaluation-deep-trench group EDTG is formed in an intersection region where the first scribe region SRBF and the second scribe region SRBS intersect each other. An insulator ZOF having a cavity AG is formed in the evaluation-deep-trench group EDTG (see FIG. 3).

In the evaluation-deep-trench group EDTG, a plurality of annular single evaluation deep trenches EDC each having a portion extending in parallel to the X-axis direction (second cleavage plane CVS2) and a portion extending in parallel to the Y-axis direction (first cleavage plane CVS1) connected to each other are formed to rectangularly expand from the center of the intersection region to the periphery thereof to be spaced apart from each other. Here, a length of the evaluation-deep-trench group EDTG in the X-axis direction is defined as a length TL5, and a length of the evaluation-deep-trench group EDTG in an axial direction is defined as a length TL6. The length TL5 and the length TL6 are larger than a width WK of the kerf region KF.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

First, a plurality of first scribe regions SRBF are sequentially diced (cut) by a dicing blade (not illustrated). As a result, as illustrated in FIG. 29, a portion of the evaluation-deep-trench group EDTG located in the kerf region KF is removed. In this case, a part of the evaluation-deep-trench group EDTG remains in the region NK of the scribe region SRB (the first scribe region SRBF and the second scribe region SRBS) that has not been removed. The part of the evaluation-deep-trench group EDTG remains in the aspect of the connection between the portion of the evaluation deep trench EDC extending along the X-axis direction and the portion of the evaluation deep trench EDC extending along the Y-axis direction.

Next, the plurality of second scribe regions SRBS is sequentially diced (cut) by a dicing blade (not illustrated). As a result, as illustrated in FIG. 30, a portion of the evaluation-deep-trench group EDTG is further removed although portions located at the four corners of the rectangular annular evaluation-deep-trench group EDTG remain. The portions located at the four corners of the evaluation-deep-trench group EDTG remain in the aspect of the connection between the portion of the evaluation deep trench EDC extending along the X-axis direction and the portion of the evaluation deep trench EDC extending along the Y-axis direction.

As described above, the element region EFR in which the semiconductor element is formed in the semiconductor wafer WAF is obtained as the semiconductor chip SCP (see FIG. 16), and the semiconductor chip SCP serving as the semiconductor device is completed.

In the above-described method of manufacturing the semiconductor device, the evaluation-deep-trench group EDTG is formed in a region where the first scribe region SRBF in parallel to the first cleavage plane CVS1 (Y-axis direction) and the second scribe region SRBS in parallel to the second cleavage plane CVS2 (X-axis direction) intersect each other.

In the evaluation-deep-trench group EDTG, a plurality of annular single evaluation deep trenches EDC each having a portion of the evaluation deep trench EDC extending in parallel to the X-axis direction (second cleavage plane CVS2) and a portion of the evaluation deep trench EDC extending in parallel to the Y-axis direction (first cleavage plane CVS1) connected to each other are formed to rectangularly expand from the center of the intersection region to the periphery thereof to be spaced apart from each other.

As a result, even if the crack occurs along the second cleavage plane CVS2 (X-axis direction) from the portion of the evaluation deep trench EDC in parallel to the X-axis in the dicing (cutting) of the first scribe region SRBF, the crack can be prevented from proceeding toward the element region EFR since the evaluation deep trench EDC in parallel to the Y-axis is connected to the end of the evaluation deep trench EDC in parallel to the X-axis.

Also, even if the crack occurs along the first cleavage plane CVS1 (Y-axis direction) from the portion of the evaluation deep trench EDC in parallel to the Y-axis in the dicing (cutting) of the second scribe region SRBS, the crack can be prevented from proceeding toward the element region EFR since the evaluation deep trench EDC in parallel to the X-axis is connected to the end of the evaluation deep trench EDC in parallel to the Y-axis.

As a result, the element region EFR (semiconductor chip) in which the semiconductor element SCE is formed can be suppressed from becoming a defective product.

Since the length TL5 in the X-axis direction and the length TL6 in the Y-axis direction of the evaluation-deep-trench group EDTG are larger than the width WK of the kerf region KF, the size of the pattern of the evaluation-deep-trench group EDTG is made large. As a result, it is possible to improve the accuracy in the optical evaluation of the evaluation-deep-trench group EDTG.

(Case 2)

In Case 2, a case where an orientation of a notch of the semiconductor wafer WAF is will be described.

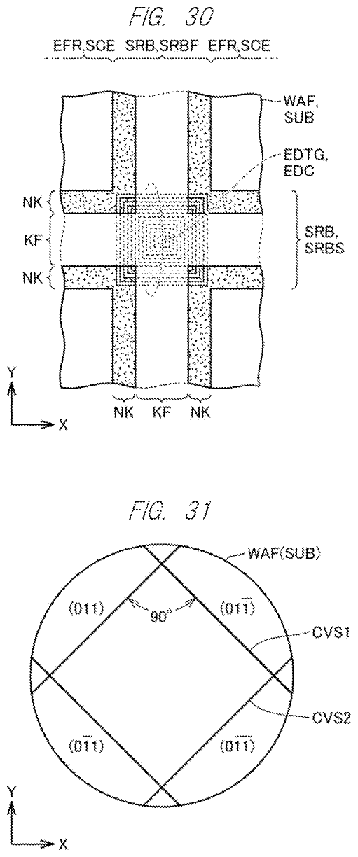

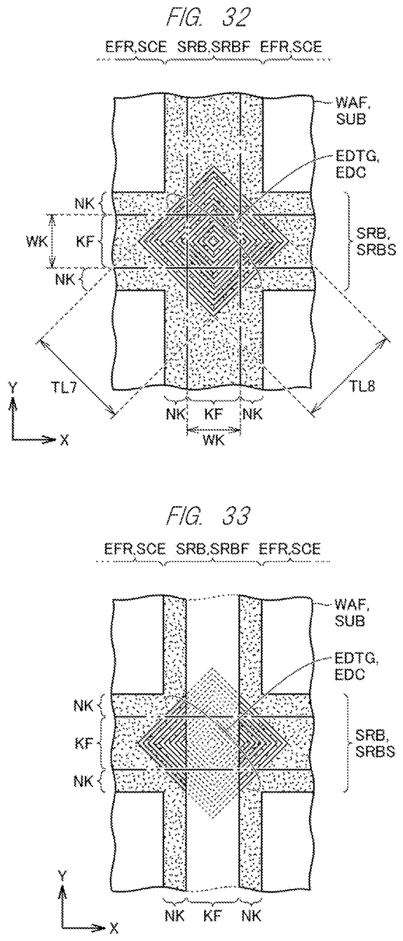

As illustrated in FIGS. 31 and 32, in the semiconductor wafer WAF that is a manufacturing target in a method of manufacturing a semiconductor device, the first cleavage plane CVS1 is in parallel to a direction (third direction) intersecting at 45° with both the X-axis direction and the Y-axis direction. The second cleavage plane CVS2 is in parallel to a direction (fourth direction) intersecting at 45° with both the X-axis direction and the Y-axis direction. The first cleavage plane CVS1 and the second cleavage plane CVS2 are orthogonal to each other.

The first scribe region SRBF is in parallel to a direction intersecting at 45° with the first cleavage plane CVS1 (Y-axis direction) and the second cleavage plane CVS2 (X-axis direction). The second scribe region SRBS is in parallel to a direction intersecting at 45° with the first cleavage plane CVS1 (Y-axis direction) and the second cleavage plane CVS2 (X-axis direction). An evaluation-deep-trench group EDTG is formed in an intersection region where the first scribe region SRBF and the second scribe region SRBS intersect each other. An insulator ZOF having a cavity AG is formed in the evaluation-deep-trench group EDTG (see FIG. 3).

In the evaluation-deep-trench group EDTG, a plurality of annular single evaluation deep trenches EDC each having a portion extending in parallel to the first cleavage plane CVS1 and a portion extending in parallel to the second cleavage plane CVS2 connected to each other are formed to rectangularly expand from the center of the intersection region to the periphery thereof to be spaced apart from each other. Here, a length in a parallel direction to the first cleavage plane CVS1 of the evaluation-deep-trench group EDTG is defined as a length TL7, and a length in a parallel direction to the second cleavage plane CVS2 of the evaluation-deep-trench group EDTG is defined as a length TL8. The length TL7 and the length TL8 are larger than the width WK of the kerf region KF.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

First, a plurality of first scribe regions SRBF are sequentially diced (cut) by a dicing blade (not illustrated). As a result, as illustrated in FIG. 33, the portion of the evaluation-deep-trench group EDTG located in the kerf region KF is removed. In this case, a part of the evaluation-deep-trench group EDTG remains in the region NK of the scribe region SRB (the first scribe region SRBF and the second scribe region SRBS) that has not been removed. The part of the evaluation-deep-trench group EDTG remains in an aspect of the connection between the portion of the evaluation deep trench EDC extending in parallel to the first cleavage plane CVS1 and the portion of the evaluation deep trench EDC extending in parallel to the second cleavage plane CVS2.

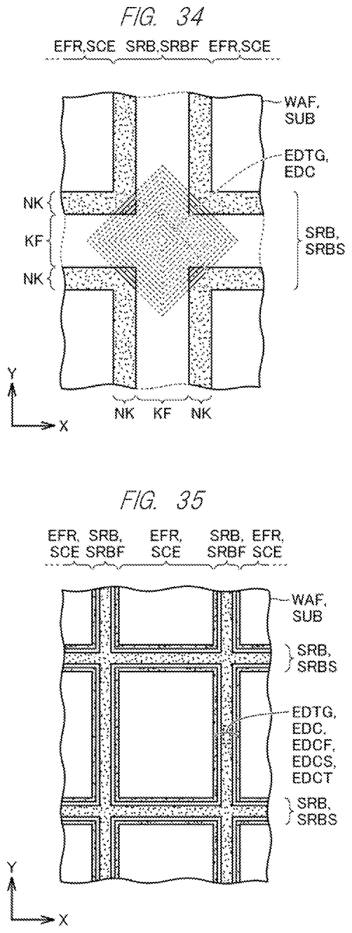

Next, the plurality of second scribe regions SRBS are sequentially diced (cut) by a dicing blade (not illustrated). As a result, as illustrated in FIG. 34, the portion of the evaluation-deep-trench group EDTG is further removed although the portion of the evaluation-deep-trench group EDTG extending in parallel to the first cleavage plane CVS1 and the portion of the evaluation-deep-trench group EDTG extending in parallel to the second cleavage plane CVS2 remain.

As described above, the element region EFR in which the semiconductor element is formed in the semiconductor wafer WAF is obtained as the semiconductor chip SCP (see FIG. 16), and the semiconductor chip SCP serving as the semiconductor device is completed.

In the above-described method of manufacturing the semiconductor device, the evaluation-deep-trench group EDTG is formed in the intersection region where the first scribe region SRBF and the second scribe region SRBS intersect each other. In the evaluation-deep-trench group EDTG, a plurality of annular single evaluation deep trenches EDC each having a portion of the evaluation deep trench EDC extending in parallel to the first cleavage plane CVS1 and a portion of the evaluation deep trench EDC extending in parallel to the second cleavage plane CVS2 connected to each other are formed to rectangularly expand from the center of the intersection region to the periphery thereof to be spaced apart from each other.

As a result, even if the crack occurs along the first cleavage plane CVS1 from the portion of the evaluation deep trench EDC in parallel to the first cleavage plane CVS1 in the dicing (cutting) of the first scribe region SRBF, the crack can be suppressed from proceeding toward the element region EFR since the evaluation deep trench EDC in parallel to the second cleavage plane CVS2 is connected to the end of the evaluation deep trench EDC in which the crack has occurred.

Even if the crack occurs along the second cleavage plane CVS2 from the portion of the evaluation deep trench EDC in parallel to the second cleavage plane CVS2 in the dicing (cutting) of the first scribe region SRBF, the crack can be suppressed from proceeding toward the element region EFR since the evaluation deep trench EDC in parallel to the first cleavage plane CVS1 is connected to the end of the evaluation deep trench EDC in which the crack has occurred.

Further, even if the crack occurs along the first cleavage plane CVS1 from the portion of the evaluation deep trench EDC in parallel to the first cleavage plane CVS1 in the dicing (cutting) of the second scribe region SRBS, a portion beyond the middle of the evaluation deep trench EDC in which the crack has occurred is already removed by the first dicing. As a result, the crack does not proceed toward the element region EFR.

Still further, even if the crack occurs along the second cleavage plane CVS2 from the portion of the evaluation deep trench EDC in parallel to the second cleavage plane CVS2, a portion beyond the middle of the evaluation deep trench EDC in which the crack has occurred is also already removed by the first dicing. As a result, the crack does not proceed toward the element region EFR.

The evaluation deep trench EDC constituting the evaluation-deep-trench group EDTG has the annular rectangular shape having the connection between the portion extending in parallel to the first cleavage plane CVS1 and the portion extending in parallel to the second cleavage plane CVS2, and intersect at 45° with both the X-axis direction and the Y-axis direction.

As a result, as similar to the description in the fourth embodiment, the size of the pattern of the evaluation-deep-trench group EDTG can be made larger than that in Case 1. As a result, it is possible to improve the accuracy in the optical evaluation of the evaluation-deep-trench group EDTG.

### Sixth Embodiment

In a sixth embodiment, a fifth example of a variation of the pattern of the evaluation deep trench EDC formed in the scribe region SRB will be described.

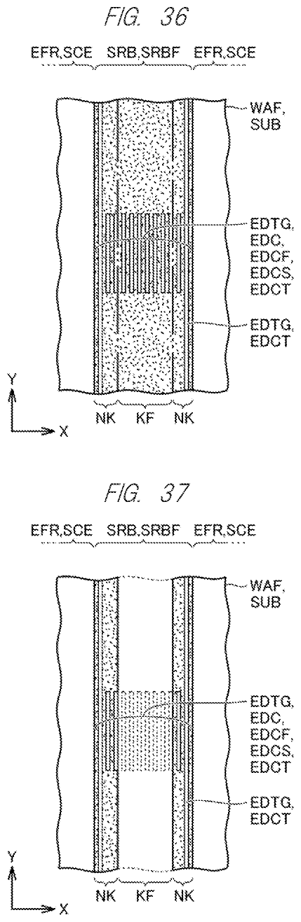

As illustrated in FIGS. 35 and 36, in the semiconductor wafer WAF that is a manufacturing target in a method of manufacturing a semiconductor device according to the sixth embodiment, an evaluation-deep-trench group EDTG made of a plurality of evaluation deep trenches EDC is formed in the first scribe region SRBF.

The plurality of evaluation deep trenches EDC include an evaluation-deep-trench-third portion EDCT (second-trench-third portion) continuously surrounding the element region EFR in addition to the evaluation deep trench EDC extending with a predetermined length in the Y-axis direction. The evaluation-deep-trench-third portion EDCT surrounding the element region EFR is formed to continuously surround the element region EFR in the region NK of the scribe region SRB located between the element region EFR and the kerf region KF to be eventually removed by the dicing blade.

Other structures including the semiconductor element SCP and the like formed in the element region EFR are similar to the configuration of the semiconductor substrate SUB (semiconductor wafer WAF) illustrated in FIG. 3 and the like, and thus, the description thereof will not be repeated unless necessary.

Next, a method of manufacturing a semiconductor device to which the above-described semiconductor wafer WAF is applied will be described. A method of sequentially manufacturing a semiconductor device is the same as that of the manufacturing steps described in the first embodiment only except that the pattern of the evaluation-deep-trench group EDTG is different from that in the first embodiment. Here, particularly, the dicing step will be described.

After manufacturing steps of sequentially forming the semiconductor element SCE on the semiconductor substrate SUB (semiconductor wafer WAF), a dicing step of obtaining, as the semiconductor chip SCP (see FIG. 16), the element regions EFR in each of which the semiconductor element SCE is formed from the semiconductor wafer WAF is performed.

First, a plurality of first scribe regions SRBF are sequentially diced (cut) by a dicing blade (not illustrated). As a result, as illustrated in FIG. 37, the evaluation deep trench EDC located in the kerf region KF is removed. In this case, the evaluation-deep-trench-third portion EDCT continuously surrounding the element region EFR remains in the region NK of the first scribe region SRBF that has not been removed.

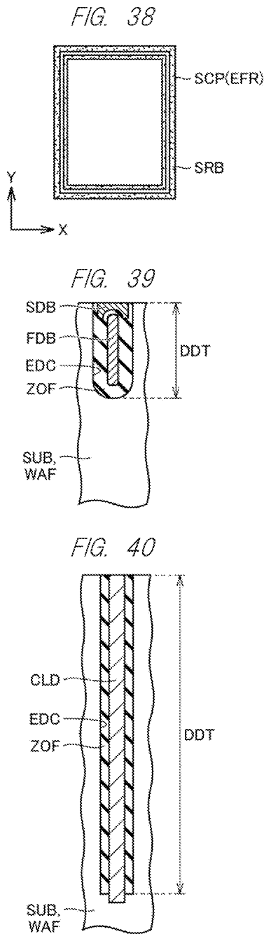

Next, the plurality of second scribe regions SRBS (see FIG. 35) are sequentially diced (cut) by a dicing blade (not illustrated). As a result, the evaluation-deep-trench-third portion EDCT continuously surrounding the element region EFR remains in the region NK of the second scribe region SRBS that has not been removed. As described above, as illustrated in FIG. 38, the element region EFR in which the semiconductor element is formed is obtained as the semiconductor chip SCP, and the semiconductor chip SCP serving as the semiconductor device is completed.

In the above-described method of manufacturing the semiconductor device, the evaluation-deep-trench-third portion EDCT is formed in the eventually remaining region NK of the scribe region SRB to continuously surround the element region EFR.

As a result, even if the crack occurs from the evaluation-deep-trench-first portion EDCF located in the kerf region KF during the dicing step, the crack can be prevented from proceeding toward the element region EFR (semiconductor chip) by the evaluation-deep-trench-third portion EDCT. As a result, the element region EFR (semiconductor chip SCP) in which the semiconductor element SCE is formed can be prevented from becoming a defective product.

### Modification Example

As described above, in each embodiment, the MOSFET having the super junction structure has been exemplified as the semiconductor element formed in the element region. In this case, the insulator ZOF having the cavity AG is formed in the deep trench DTC (see FIG. 3) formed in the element region EFR. Consequently, the insulator ZOF having the cavity AG is also formed in the evaluation deep trench EDC constituting the evaluation-deep-trench group EDTG formed in the scribe region.

As the semiconductor element formed in the element region, for example, a field plate type field effect transistor (see the Patent Document 2) is exemplified in addition to the semiconductor element having the super junction structure. In this case, a field plate and a gate electrode are formed in the deep trench formed in the element region (not illustrated).

Accordingly, as illustrated in FIG. 39, in the scribe region SRB, a first conductor FDB corresponding to the field plate and a second conductor SDB corresponding to the gate electrode are formed in the evaluation deep trench EDC constituting the evaluation-deep-trench group EDTG. The first conductor FDB and the second conductor SDB are electrically insulated from each other by the insulator ZOF. In this case, the depth DDT of the evaluation deep trench EDC is, for example, about several μm.

As the semiconductor element formed in the element region, a semiconductor element in which a substrate contact is formed in one deep trench and an element separator is formed in another deep trench (see the Patent Document 3) is exemplified. In this case, a metal such as tungsten is formed in one deep trench, and an insulator having a cavity is formed in another deep trench (both not illustrated).

Accordingly, as illustrated in FIG. 40, in the scribe region SRB, a conductor CLD corresponding to a metal such as tungsten is formed via the insulator ZOF in the evaluation deep trench EDC constituting the evaluation-deep-trench group EDTG. In this case, the depth DDT of the evaluation deep trench EDC is, for example, about several tens of μm. In another evaluation deep trench, an insulator having a cavity is formed (not illustrated).

The methods of manufacturing the semiconductor device or the semiconductor wafer described in the respective embodiments may be variously combined with one another as necessary.

The semiconductor wafer according to each embodiment includes the following aspects.

[First Statement]

A semiconductor wafer including a semiconductor element formed in each of a plurality of element regions defined in a semiconductor substrate, includes:
the semiconductor substrate having a main surface;
a plurality of scribe regions defined in the main surface of the semiconductor substrate, including a plurality of first scribe regions each extending in a first direction and arranged to be spaced apart from each other in a second direction intersecting the first direction;
the plurality of element regions defined in a matrix form by the plurality of scribe regions in the main surface of the semiconductor substrate, and each including a first trench formed therein;
the semiconductor element formed in each of the plurality of element regions; and
a trench group formed in the first scribe region, and comprised of a plurality of second trenches,
the trench group comprised of the plurality of second trenches includes:
a second-trench-first portion formed in a first region of one of the plurality of first scribe regions; and
a second-trench-second portion formed in a second region of the one of the plurality of first scribe regions, the second region being located between the first region of the one of the plurality of first scribe regions and one of the plurality of element regions, and the one of the plurality of element regions being adjacent to the one of the plurality of first scribe regions including the first region, and
in plan view, the second-trench-second portion is formed in a bar shape extending in the first direction in which each of the plurality of first scribe regions extends.

[Second Statement]

In the semiconductor wafer according to FIRST STATEMENT,
the second-trench-first portion has a first length in the first direction, and
the second-trench-second portion has a second length equal to or larger than the first length in the first direction.

[Third Statement]

In the semiconductor wafer according to FIRST STATEMENT,
the plurality of scribe regions include a plurality of second scribe regions each extending in the second direction and arranged to be spaced apart from each other in the first direction in the main surface of the semiconductor substrate, and
the trench group is formed in an intersection region of the first scribe region intersecting the second scribe region.

[Fourth Statement]

In the semiconductor wafer according to FIRST STATEMENT, the trench group comprised of the plurality of second trenches includes a second-trench-third portion formed in the second region of the scribe region to annularly surround the element region.

[Fifth Statement]

In the semiconductor wafer according to any one of FIRST to FOURTH STATEMENTS, an insulating member is formed in each of the trench group and the first trench such that the insulating member formed in each of the trench group and the first trench has a cavity therein.

[Sixth Statement]

In the semiconductor wafer according to any one of FIRST to FOURTH STATEMENTS, each of the trench group and the first trench has a depth of at least 1.0 μm.

[Seventh Statement]

A semiconductor wafer including a semiconductor element formed in each of a plurality of element regions defined in a semiconductor substrate, includes:
the semiconductor substrate having a main surface; and
a plurality of first scribe regions defined in the main surface of the semiconductor substrate, each extending in a first direction and arranged to be spaced apart from each other in a second direction intersecting the first direction, and a plurality of second scribe regions each extending in the second direction and arranged to be spaced apart from each other in the first direction;
the plurality of element regions defined in a matrix form by the plurality of first scribe regions and the plurality of second scribe regions in the main surface of the semiconductor substrate, and each including a first trench formed therein;
a trench group comprised of a plurality of second trenches formed in an intersection region where the first scribe region and the second scribe region intersect each other; and
the semiconductor element formed in each of the plurality of element regions,
each of the first scribe region and the second scribe region includes:
a first region; and
a second region located between the first region of the one of the plurality of first scribe regions and one of the plurality of element regions, and the one of the plurality of element regions being adjacent to the first scribe region or the second scribe region, and
the trench group comprised of the plurality of second trenches is formed so that all of the plurality of second trenches are located in the first region in the intersection region.

[Eighth Statement]

In the semiconductor wafer according to SEVENTH STATEMENT,
the plurality of second trenches of the trench group each are formed in a bar shape extending in a third direction intersecting the first direction and the second direction, and are formed to be spaced apart from each other in a fourth direction intersecting the first direction, the second direction and the third direction, and
a length of the plurality of second trenches in the third direction and a length of the plurality of second trenches in the fourth direction are larger than a width of the first region, and are smaller than a value of a product of widths of the first scribe region and the second scribe region and a square root of 2.

[Ninth Statement]

In the semiconductor wafer according to SEVENTH or EIGHTH STATEMENT, an insulating member is formed in each of the trench group and the first trench such that the insulating member formed in each of the trench group and the first trench has a cavity therein.

[Tenth Statement]

In the semiconductor wafer according to SEVENTH or EIGHTH STATEMENT, each of the trench group and the first trench has a depth of at least 1.0 μm.

[Eleventh Statement]

A semiconductor wafer including a semiconductor element formed in each of a plurality of element regions defined in a semiconductor substrate, includes:
the semiconductor substrate having a main surface;
a plurality of first scribe regions defined in the main surface of the semiconductor substrate, each extending in a first direction and arranged to be spaced apart from each other in a second direction intersecting the first direction, and a plurality of second scribe regions each extending in the second direction and arranged to be spaced apart from each other in the first direction;
the plurality of element regions defined in a matrix form by the plurality of first scribe regions and the plurality of second scribe regions in the main surface of the semiconductor substrate, and each including a first trench formed therein;
a trench group comprised of a plurality of second trenches formed in an intersection region where the first scribe region and the second scribe region intersect each other; and
the semiconductor element formed in each of the plurality of element regions, and
each of the plurality of second trenches of the trench group is annularly formed to extend along a cleavage plane of the semiconductor substrate.

[Twelfth Statement]

In the semiconductor wafer according to ELEVENTH STATEMENT,
the cleavage plane includes:
a first cleavage plane in parallel to the first direction; and
a second cleavage plane in parallel to the second direction.

[Thirteenth Statement]

In the semiconductor wafer according to ELEVENTH STATEMENT,
the cleavage plane includes:
a first cleavage plane in parallel to a third direction intersecting each of the first direction and the second direction; and
a second cleavage plane in parallel to a fourth direction intersecting each of the first direction, the second direction and the third direction.

[Fourteenth Statement]

In the semiconductor wafer according to any one of ELEVENTH to THIRTEENTH STATEMENTS, an insulator having a cavity is formed in each of the trench group and the first trench.

[Fifteenth Statement]

In the semiconductor wafer according to any one of the ELEVENTH to THIRTEENTH STATEMENTS, each of the trench group and the first trench has a depth of at least 1.0 μm.

[Sixteenth Statement]

A method of manufacturing a semiconductor device, includes:
a step (a) of preparing a semiconductor substrate including an element region having one side and a scribe region formed to extend along the one side of the element region in plan view;
a step (b) of, after the step (a), forming a first trench in the element region and forming a plurality of second trenches in the scribe region;
a step (c) of, after the step (b), evaluating the plurality of second trenches; and
a step (d) of, after the step (c), cutting the semiconductor substrate by causing a dicing blade to travel along the scribe region to acquire a semiconductor chip having the element region,
in plan view, the scribe region includes:
a first region removed by the dicing blade in the step (d); and
a second region located between the first region and the element region adjacent to the scribe region, and not being removed by the dicing blade in the step (d),
the plurality of second trenches formed in the step (b) include, in plan view,
a plurality of second-trench-first portions formed in the first region; and
a second-trench-second portion formed in the second region, and located adjacent to the plurality of second-trench-first portions, and
in the step (b), the second-trench-second portion is formed to extend along the one side of the element region in plan view.

[Seventeenth Statement]

In the method of manufacturing the semiconductor device according to SIXTEENTH STATEMENT, in the step (b), the second-trench-first portion is formed to extend along the one side of the element region in plan view.

[Eighteenth Statement]

In the method of manufacturing the semiconductor device according to SEVENTEENTH STATEMENT, in the step (b), a second-trench-third portion is formed between the element region and the second-trench-second portion in the second region to extend along the one side of the element region in plan view.

[Nineteenth Statement]

In the method of manufacturing the semiconductor device according to SIXTEENTH STATEMENT, in the step (b), the second-trench-first portion is formed to extend along a second direction intersecting a first direction in which the one side of the element region extends in plan view.

[Twentieth Statement]

In the method of manufacturing the semiconductor device according to SIXTEENTH STATEMENT, in the step (c), a shape of the first trench is evaluated by evaluating the plurality of second trenches.

In the foregoing, the invention made by the inventors of the present application has been concretely described on the basis of the embodiments. However, it is needless to say that the present invention is not limited to the foregoing embodiments, and various modifications and alterations can be made within the scope of the present invention.

What is claimed is:

1. A method of manufacturing a semiconductor device including a semiconductor element formed in each of a plurality of element regions defined in a semiconductor substrate, comprising steps of:
preparing the semiconductor substrate having a main surface;
defining a plurality of scribe regions in the main surface of the semiconductor substrate, the plurality of scribe regions including a plurality of first scribe regions each extending in a first direction and arranged to be spaced apart from each other in a second direction intersecting the first direction;
forming the semiconductor element in each of the plurality of element regions defined in a matrix form by the plurality of scribe regions; and
obtaining the plurality of element regions in each of which the semiconductor element is formed, as a semiconductor chip, by cutting each of the plurality of scribe regions with a dicing blade,
wherein the step of forming the semiconductor element includes steps of:
forming a first trench in each of the plurality of element regions, and forming a trench group comprised of a plurality of second trenches in each of the plurality of first scribe regions; and
evaluating the trench group,
wherein the step of forming the trench group comprised of the plurality of second trenches includes a step of forming a second-trench-first portion in a first region of one of the plurality of first scribe regions to be removed by the dicing blade, and forming a second-trench-second portion in a second region of the one of the plurality of first scribe regions, the second region being located between the first region of the one of the plurality of first scribe regions and one of the plurality of element regions, and the one of the plurality of element regions being adjacent to the one of the plurality of first scribe regions including the first region, and
wherein, in plan view, the second-trench-second portion is formed in a bar shape extending in the first direction in which each of the plurality of first scribe regions extends.

2. The method of manufacturing the semiconductor device according to claim 1,
wherein the second-trench-first portion has a first length in the first direction, and
wherein the second-trench-second portion is formed to have a second length equal to or larger than the first length in the first direction.

3. The method of manufacturing the semiconductor device according to claim 1,
wherein the step of defining the plurality of scribe regions includes a step of defining a plurality of second scribe regions each extending in the second direction and arranged to be spaced apart from each other in the first direction, in the main surface of the semiconductor substrate,
wherein the step of forming the trench group includes a step of forming the trench group in a portion of the one of the plurality of first scribe regions, the portion of the one of the plurality of first scribe regions intersecting one of the plurality of second scribe regions, and
wherein the step of obtaining the semiconductor chip includes:
a first dicing step of cutting the one of the plurality of first scribe regions with the dicing blade; and
a second dicing step of cutting the one of the plurality of second scribe regions with the dicing blade after the first dicing step.

4. The method of manufacturing the semiconductor device according to claim 1,
wherein the step of forming the trench group comprised of the plurality of second trenches includes a step of forming a second-trench-third portion in a portion of the one of the plurality of scribe regions including the second region of the one of the plurality of first scribe regions to be not removed by the dicing blade so as to annularly surround the one of the plurality of element regions.

5. The method of manufacturing the semiconductor device according to claim 1,
wherein after the step of evaluating the trench group, the step of forming the semiconductor element includes a step of embedding an insulating member into each of the trench group and the first trench such that the insulating embedded into each of the trench group and the first trench member has a cavity therein.

6. The method of manufacturing the semiconductor device according to claim 1,
wherein, in the step of forming the semiconductor element, each of the trench group and the first trench is formed to have a depth of at least 1.0 μm.

7. The method of manufacturing the semiconductor device according to claim 1,
wherein, in the step of evaluating the trench group, the trench group is optically evaluated.

8. A method of manufacturing a semiconductor device including a semiconductor element formed in each of a plurality of element regions defined in a semiconductor substrate, comprising steps of:
preparing the semiconductor substrate having a main surface;
defining, in the main surface of the semiconductor substrate, a plurality of first scribe regions each extending in a first direction and arranged to be spaced apart from each other in a second direction intersecting the first direction, and a plurality of second scribe regions each extending in the second direction and arranged to be spaced apart from each other in the first direction;
forming the semiconductor element in each of the plurality of element regions defined in a matrix form by the plurality of first scribe regions and the plurality of second scribe regions; and
obtaining the plurality of element regions in each of which the semiconductor element is formed, as a semiconductor chip, by cutting the first scribe region and the second scribe region with a dicing blade,
wherein the step of forming the semiconductor element includes steps of:
forming a first trench in each of the plurality of element regions and forming a trench group comprised of a plurality of second trenches in an intersection region where the first scribe region and the second scribe region intersect each other, and
evaluating the trench group, and
wherein, in the step of forming the trench group, all of the plurality of second trenches are formed to be located in a portion of the intersection region, the portion to be removed by the dicing blade.

9. The method of manufacturing the semiconductor device according to claim 8,
wherein, in the step of forming the trench group, the plurality of second trenches each are formed in a bar shape extending in a third direction intersecting the first direction and the second direction, and are formed to be spaced apart from each other in a fourth direction intersecting the first direction, the second direction and the third direction, and
wherein a length of the plurality of second trenches in the third direction and a length of the plurality of second trenches in the fourth direction are larger than a width removed by the dicing blade, and are smaller than a value of a product of widths of the first scribe region and the second scribe region and a square root of 2.

10. The method of manufacturing the semiconductor device according to claim 8,
wherein after the step of evaluating the trench group, the step of forming the semiconductor element includes a step of embedding an insulating member into each of the trench group and the first trench such that the insulating member embedded into each of the trench group and the first trench has a cavity therein.

11. The method of manufacturing the semiconductor device according to claim 8,
wherein, in the step of forming the semiconductor element, each of the trench group and the first trench is formed to have a depth of at least 1.0 μm.

12. The method of manufacturing the semiconductor device according to claim 8,
wherein, in the step of evaluating the trench group, the trench group is optically evaluated.

13. A method of manufacturing a semiconductor device including a semiconductor element formed in each of a plurality of element regions defined in a semiconductor substrate, comprising steps of:
preparing the semiconductor substrate having a main surface;
defining, in the main surface of the semiconductor substrate, a plurality of first scribe regions each extending in a first direction and arranged to be spaced apart from each other in a second direction intersecting the first direction, and a plurality of second scribe regions each extending in the second direction and arranged to be spaced apart from each other in the first direction;
forming the semiconductor element in each of the plurality of element regions defined in a matrix form by the plurality of first scribe regions and the plurality of second scribe regions; and
obtaining the plurality of element regions in each of which the semiconductor element is formed, as a semiconductor chip, by cutting the first scribe region and the second scribe region with a dicing blade,
wherein the step of forming the semiconductor element includes steps of:
forming a first trench in each of the plurality of element regions and forming a trench group comprised of a plurality of second trenches in an intersection region where the first scribe region and the second scribe region intersect each other; and
evaluating the trench group, and
wherein, in the step of forming the trench group comprised of the plurality of second trenches, each of the plurality of second trenches is annularly formed to extend along a cleavage plane of the semiconductor substrate.

14. The method of manufacturing the semiconductor device according to claim 13,
wherein the cleavage plane includes:
a first cleavage plane in parallel to the first direction; and
a second cleavage plane in parallel to the second direction.

15. The method of manufacturing the semiconductor device according to claim 13,
wherein the cleavage plane includes:
a first cleavage plane in parallel to a third direction intersecting the first direction and the second direction; and
a second cleavage plane in parallel to a fourth direction intersecting the first direction, the second direction and the third direction.

16. The method of manufacturing the semiconductor device according to claim 13,
wherein after the step of evaluating the trench group, the step of forming the semiconductor element includes a step of embedding an insulating member into each of the trench group and the first trench such that the insulating member embedded into each of the trench group and the first trench has a cavity therein.

17. The method of manufacturing the semiconductor device according to claim 13,
wherein, in the step of forming the semiconductor element, each of the trench group and the first trench is formed to have a depth of at least 1.0 μm.

18. The method of manufacturing the semiconductor device according to claim 13,
wherein, in the step of evaluating the trench group, the trench group is optically evaluated.
